(19) United States
(12) Patent Application Publication
(10) Pub. No.: US 2006/0065439 A1
(43) Pub. Date: Mar. 30, 2006

(54) Wiring board and wiring board manufacturing method

(75) Inventor: Yasunobu Oikawa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK Corporation, Tokyo (JP)

(21) Appl. No.: 11/233,182

(22) Filed: Sep. 23, 2005

(30) Foreign Application Priority Data
Sep. 30, 2004 (JP) 2004-285761

(51) Int. Cl. H05K 1/11; H05K 3/42

(52) U.S. Cl. 174/264; 216/18

(57) ABSTRACT

The present invention provides a wiring board including a metal plate that has a through hole formed so as to pass though both surfaces thereof by isotropic etching; an insulating layer that covers both surfaces of the metal plate and the inside surface of the through hole; a wiring layer formed on an upper surface of at least one surface of the insulating layer on; and a conductive via electrode formed in the through hole, wherein a diameter of the through hole is 100 μm or less and a ratio of a thickness of the metal plate to the diameter of the through hole is 1 or more, preferably, 1.2 or more.

### DETAILED DESCRIPTION OF THE INVENTION

1. Technical Field Pertinent to the Invention

The invention relates to a wiring board for mounting electric devices using a metal plate as a core material, and a method for manufacturing the wiring board.

2. Prior Art

For the purpose of preventing a signal reflection caused by an impedance mismatch of a conductive via electrode of the wiring board and cross talk between terminals, and of eliminating a design error in an element constant caused by thermal contraction and surface roughness at a time of sintering when a ceramic board is used and of eliminating a problem of heat resistance presented when an organic insulating resin board is used, a wiring board for mounting electric devices is disclosed (see, for example, patent Literature 1) in which a base board constructing the wiring board is constructed of a metal material and in which a conductive via electrode for electrically connecting both surfaces of the base board has a coaxial structure.

There is a trend for electric devices such as IC chips in recent years to become more versatile and more sophisticated in functionality and, with this trend, a number of connections between an IC chip and a circuit board is increasing. On the other hand, in order to improve the function of the IC chip and to reduce its cost, in a wiring rule of the IC, a pattern has been shrunk to narrow the pitch of connection terminals. The narrowing of the pitch of connection terminals inevitably reduces the diameters of through holes of the wiring board. In particular, in recent years, the diameter of the through hole of the wiring board has been required to be 100 μm or less.

In the case of manufacturing a wiring board having a metal plate as a base board and provided with many through holes or conductive via electrodes, it is thought that a manufacturing method of using etching or laser is used for forming a through hole having a diameter of 100 μm or less.

In the case of etching the metal plate, in the related art has been employed a method for forming a through hole in the metal plate by a process in which both surfaces of the metal plate are once coated with a photoresist, exposed to light, developed, and etched. According to this method, in the case of forming a through hole having a diameter of 100 μm or less, a ratio of a thickness of the metal plate to the diameter of the through hole is practically, at most, 0.7 or less. If isotropic etching is used, even if the diameter of the through hole is 100 μm or less, the ratio of the thickness of the metal plate to the diameter of the through hole can be 0.7 or less, however, the isotropic etching takes much etching time and requires a large-scale etching apparatus.

Even in the case of utilizing laser, it is difficult to make the ratio of the thickness of the metal plate to the diameter of the through hole 0.7 or more. Moreover, it requires a great deal of time and labor to remove metal block melted by the heat of laser.

On the other hand, in order to reduce the diameter of the through hole, it is also thought that the thickness of the metal plate to be abase plate is reduced, but the metal plate is required to have a certain thickness so as to provide the wiring board with a measure of strength. Moreover, there is a tendency that the pitch of electrode pins of the IC mounted on the wiring board becomes narrower and hence, in order to narrow the pitch of the through holes under this condition, the diameter of the though hole is required to be smaller than the thickness of the board.

While a request for reducing the diameter of the though hole to 100 μm or less is increasing in recent years for the higher density packaging of the wiring board, there is presented a problem that a conventional manufacturing method in the related art can not respond to the wiring board having a metal plate as a base board.

[Patent Literature 1] Japanese Patent Application Laid-Open No. 2001-15654

### SUMMARY OF THE INVENTION

[Problems that this Invention is to Solve]

In order to solve the above-described problem, it is an object of the invention to provide a wiring board which has a base board constructed of a metal material and is provided with a conductive via electrode for electrically connecting both surfaces of the base board and has through holes each having a small diameter, wherein a ratio of a thickness of the metal plate to the diameter of the through hole is made large. In addition, it is also an object of the invention to provide a method for manufacturing such the wiring board.

[Means for Solving the Problems]

The first invention of this application is a wiring board including: a metal plate that has a through hole formed so as to pass though both surfaces thereof by isotropic etching; an insulating layer that covers both surfaces of the metal plate and an inside surface of the through hole; a wiring layer formed on an upper surface of the insulating layer on at least one surface; and a conductive via electrode formed in the through hole, wherein a diameter of the through hole is 100 μm or less and a ratio of a thickness of the metal plate to the diameter of the through hole is 1 or more. In other words, the wiring board is characterized in that the thickness of the metal plate is thicker than the diameter of the though hole formed by isotropic etching. However, it is preferable that the ratio of the thickness of the metal plate to the diameter of the through hole is 1.2 or more.

The first invention of this application includes a wiring board in which the isotropic etching is wet etching.

The second invention of this application includes such a method for manufacturing a wiring board that includes the steps of, so as to form a through hole in the metal plate: subjecting one surface or both surfaces of a metal plate to photoresist coating at least one time, and then to exposing, developing, and isotropic etching; and subjecting both surfaces of the metal plate to photoresist coating at least one time, and then to exposing, developing, and isotropic etching.

The second invention of this application includes a method for a manufacturing a wiring board in which the isotropic etching is wet etching.

The second invention of this application includes a method for manufacturing a wiring board in which a photoresist coating after at least two times is performed by electrodeposition.

[Effect of the Invention]

According to this invention, it is possible to make a wiring board mounted with an electric device more sophisticated in functionality and of higher density in packaging. Moreover, it is possible to make a manufacturing process of the wiring board economical.

### BRIEF DESCRIPTION OF THE DRAWINGS

[FIG. 1]

FIG. 1 is an illustration to describe the embodiment of a wiring board of the invention and is a cross sectional view of the wiring board.

[FIG. 2]

FIGS. 2A to 2D are illustrations to describe a method for manufacturing a wiring board of the invention and illustrate a process for forming a through hole in a metal plate.

[FIG. 3]

FIGS. 3A to 3D are illustrations to describe a method for manufacturing a wiring board of the invention and illustrate a process for forming a through hole in the metal plate.

[FIG. 4]

FIGS. 4A to 4D are illustrations to describe a method for manufacturing a wiring board of the invention and illustrate a process for forming a conductive film to be the connecting electrode of a passive element on a conductive via electrode of a wiring board.

10 denotes Wiring board, 11 denotes Metal plate, 12 denotes Insulating layer, 13 denotes Conductive via electrode, 14 denotes Connecting electrode of a passive element, 21 denotes Photoresist, 22 denotes Photo-mask, 23 denotes Photoresist, 24 denotes Photo-mask, 25 denotes Through hole.

### DESCRIPTION OF PREFERRED EMBODIMENTS

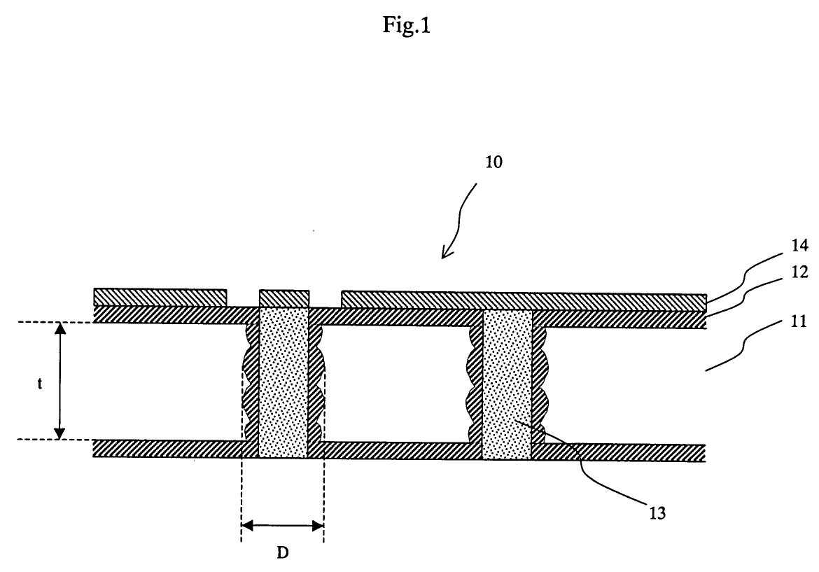

Hereafter, the best mode for carrying out the invention will be described with reference to the accompanying drawings. FIG. 1 is an illustration to describe an embodiment of a wiring board of the invention and is a cross sectional view of the wiring board. In FIG. 1, a reference numeral 10 denotes a wiring board, 11 denotes a metal plate, 12 denotes an insulating layer, 13 denotes a conductive via electrode, 14 denotes a connecting electrode with a passive element, a reference symbol D denotes the diameter of a through hole, and t denotes the thickness of the metal plate 11.

A wiring board 10 has a metal plate 11 having a through hole made so as to pass both surfaces by isotropic etching, an insulating layer 12 covering both surfaces of the metal plate 11 and the inner surface of the through hole, a connecting electrode 14 with the passive element as a part of a wiring layer formed on the upper surface of the insulating layer, and a conductive via electrode 13 formed in the through hole. It is recommended that a capacitor, a resistance or an inductance as a passive element be formed on one surface of the wiring board 10.

Copper, invar, or 42-alloy is desirable as a material of a metal plate 11. When copper as the material of the metal plate 11 is used, copper has high thermal conductivity, so it can increase thermal dissipation efficiency even if a power consumption of an IC chip is large. When invar is used, since invar has a small thermal expansion coefficient, it can prevent the wiring board from being expanded by heat. When 42-alloy is used, since the 42-alloy is nearly equal to Si in thermal expansion coefficient, even if the electric device and the metal plate are expanded by heat, an effect of strain caused by heat on the IC chip and the metal plate is small.

By constructing a base board constructing the wiring board 10 of the metal plate 11 and by making the structure of the conductive via electrode 13 for electrically connecting both surfaces of the wiring board a coaxial structure, it is possible to prevent a signal reflection caused by the impedance mismatch of the conductive via electrode 13 of the wiring board and crosstalk between terminals, to eliminate a design error in an element constant caused by thermal contraction and a surface roughness at a time of sintering when a ceramic-based board is used, and to eliminate a problem of heat resistance presented when an organic insulating resin board is used.

In the through hole of the metal plate shown in FIG. 1, a diameter D of the through hole is 100 μm or less and a ratio t/D of a thickness t of the metal plate 11 to the diameter D of the through hole is 1 or more, preferably, 1.2 or more. The invention is characterized in that the through hole is formed by isotropic etching. Since the through hole is formed by the isotropic etching, the inside surface of the through hole is not a smooth surface but has the traces of side etching left thereon. The use of isotropic etching can provide an advantage of forming the through hole by a simple etching apparatus and an advantage of completing an etching process in a short time. Furthermore, since the diameter of the through hole can be made small, the high-density packaging of the wiring board can be realized. Wet etching is desirable as the isotropic etching. The wet etching has an advantage of making an etching process shorter than dry etching.

In order to make the diameter D of the through hole 100 μm or less and to make the ratio of the thickness t of metal plate 11 to the diameter D of through hole 1 or more, preferably, 1.2 or more, one time of isotropic etching is not sufficient but a plurality of times of isotropic etching is required. Hence, traces of a plurality of times of side etching are left on the inside surface of the through hole.

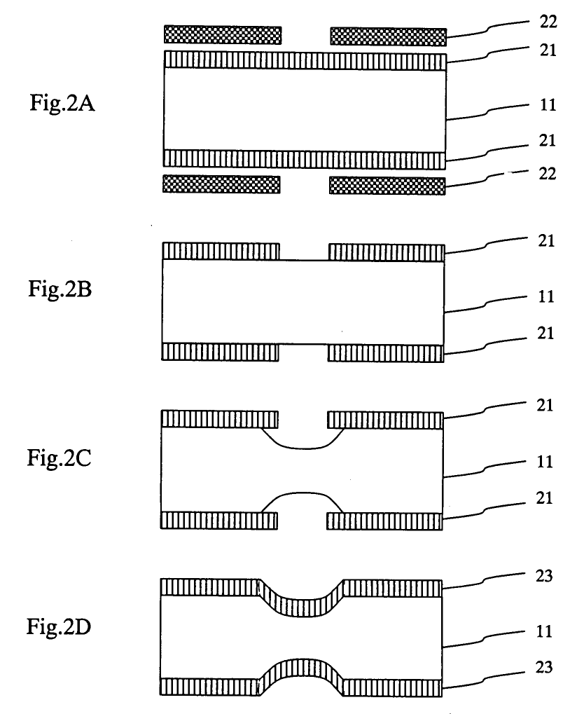

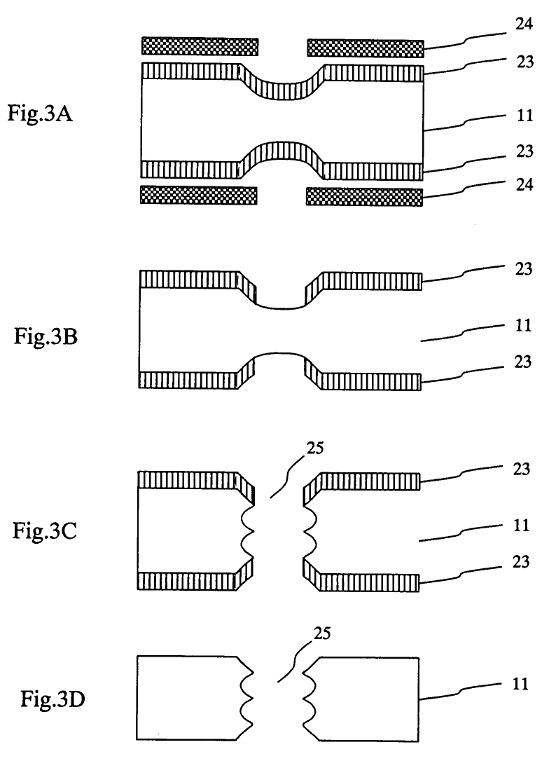

Next, an embodiment of a method for manufacturing a wiring board, by which a through hole is formed in a metal plate used for the wiring board, will be described. FIG. 2 and FIG. 3 are figures illustrating the method for manufacturing the wiring board of the invention and show processes for forming a through hole in a metal plate. In FIG. 2 and FIG. 3, a reference numeral 11 denotes a metal plate, 21 denotes a photoresist, 22 denotes a photo-mask, 23 denotes a photoresist, 24 denotes a photo-mask, and 25 denotes a through hole.

In order to form a through hole 25 in the metal plate 11, the method includes a process of subjecting one surface or both surfaces of the metal plate 11 to photoresist coating at least one time, exposing, developing, and isotropic etching, and further another process of subjecting both surfaces of the metal plate 11 to photoresist coating at least one time, exposing, developing, and isotropic etching. FIGS. 2A, 2B, 2C show the first process of photoresist coating, exposing, developing, and isotropic etching.

First, the surface of the metal plate 11 to be a base board of the wiring board is subjected to a degreasing and cleaning treatment. Both surfaces of the metal plate 11 subjected to the degreasing and cleaning treatment is coated with a positive photoresist 21 and is exposed to light by the use of a photo-mask 22 for exposing portions where through holes are to be formed to the light (FIG. 2A). A method for coating a photoresist includes spin coat, dip coat, roll coat, and spray coat. Here, in order to etch both surfaces at the same time, both surfaces are masked with the photo-masks and exposed to light. In a case of etching only one surface, the other surface not to be etched is prevented from being exposed to light.

Then, patterns at the exposed portions are developed and the photoresist on the exposed portions are removed (FIG. 2B). The metal plate 11 having the portions of photoresist 21 removed is immersed in an etching solution to perform half etching (FIG. 2C). Here, wet etching of isotropic etching is performed. The use of wet etching can make an etching apparatus simple and complete an etching process in a short time.

FIGS. 2D, 3A, 3B, 3C, and 3D show the second process of photoresist coating, exposing, developing, and isotropic etching. Both surfaces of the metal plate 11 subjected to etching are coated with a positive photoresist 24 (FIG. 2D). At this time, it is also recommended that the photoresist 24 be overlaid on the photoresist 21 used for the half etching without removing or the photoresist 24 be applied after removing the photoresist 21. A method of coating a photoresist may be spin coat, dip coat, roll coat, or spray coat, but in order to coat with the photoresist to also the depressions subjected to the half etching with, an electrodeposition photoresist coating is desirable. Since an object is made of metal, it can be coated with the electrodeposition photoresist.

The photoresist is exposed to light by the use of the photo-mask 24 for exposing portions where the through holes are to be formed to light (FIG. 3A). The photo-mask 22 used for the half etching may be used as the photo-mask 24 or a different photo-mask may be used so as to adjust the sizes of portions to be exposed.

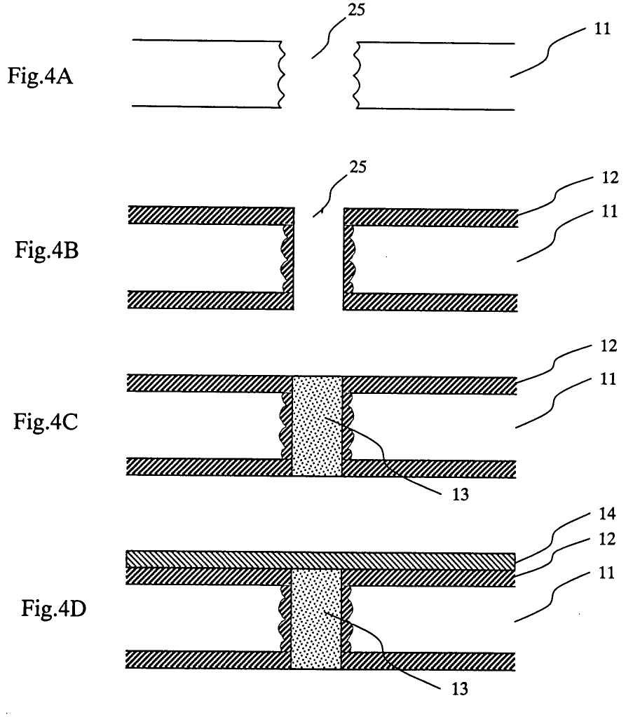

Next, the patterns of the exposed portions is developed and the photoresist on the exposed portions is removed (FIG. 3B). The metal plate 11 having portions of the photoresist 23 removed is immersed in the etching solution, thereby being etched (FIG. 3C). Here, the metal plate 11 is etched by the wet etching of isotropic etching. The photoresist 23 is removed to make a through hole 25 (FIG. 3D). As shown in FIG. 3-4, the through hole is formed by the isotropic etching, so the side etching traces are left on the inside surface of the through hole. Moreover, if the isotropic etching is performed a plurality of times, a plurality of side etching traces are left, and if both surfaces are subjected to wet etching a plurality of times, a plurality of side etching traces are left in the direction of thickness from both surfaces of the metal plate 11.

In this embodiment, the through holes are made by two operations of etching, but may be made by two or more operations of etching. Moreover, in this embodiment, the positive photoresist is used, but a negative photoresist may be used. When the negative photoresist is used, in FIG. 2 or FIG. 3, the photo-mask is placed at positions where the through holes are to be formed to prevent the photoresist at the positions where the through holes are to be formed from being exposed to light. Since the through holes are formed by the isotropic etching, a small-scale etching apparatus can be used and further the use of wet etching among the isotropic etching can reduce the time required for etching and hence can simplify the process for manufacturing the wiring board.

According to the method for manufacturing such the wiring board, even if the diameter of the through hole is 100 μm or less and the ratio of the thickness of the metal plate to the diameter of the through hole is 1 or more, the through holes can be formed in the metal plate with ease. Further, even if the ratio of the thickness of the metal plate to the diameter of the through hole is 1.2 or more, the through holes can be formed in the metal plate without impairment of ease.

The insulating layer 12 is formed on both surfaces of the metal plate 11 (FIG. 4A) manufactured in the above embodiment and having the through hole 25 and the inside surface of the through hole 25 (FIG. 4B). A method for laminating an inorganic insulating layer includes physical methods such as sputtering, deposition methods such as a chemical vapor deposition method, coating methods such as a sol-gel method, a MOD method, and a plating method, and the like. A method for laminating an organic insulating layer includes dip methods or spray methods for applying a resin material such as polyimide, polyamide, epoxy, BT (Bismalimide Triazone), and the like. Here, a SiO₂ film is formed by a P-CVD method (Plasma Chemical Vapor Deposition).

Next, the conductive via electrode 13 is formed in the through hole 25 (FIG. 4C). It is also recommended that the inside of the through hole be filled with metal such as copper or a metal film be cylindrically formed on the inside wall of the through hole 25 and then a central portion be filled with resin by a printing method or the like. If necessary, the surface of the wiring board of the conductive via electrode is planarized by polishing or back etching.

A conductive film to be the connecting electrode 14 of the electric device mounted on a wiring board is formed (FIG. 4D). And the formed conductive film is patterned by etching or the like to form the connecting electrode (FIG. 1). As to a method for forming the conductive film, the conductive film is formed by one of vacuum film forming methods, such as sputtering or vapor deposition, or wet film forming methods, such as plating, using conductive metal such as copper, platinum, silver, and nickel.

In the wiring board manufactured in this manner, by constructing the base board constructed of the metal plate 11 and by making the structure of the conductive via electrode 13 for electrically connecting both surfaces of the wiring board a coaxial structure, it is possible to prevent a signal reflection caused by the impedance mismatch of the conductive via electrode 13 of the wiring board and crosstalk between terminals, to eliminate a design error in an element constant caused by thermal contraction or a surface roughness at a time of sintering when a ceramic-based board is used, and to eliminate a problem of heat resistance presented when an organic insulating board is used.

Moreover, in the metal plate which is the base board of the wiring board, the diameter of the through hole is 100 μm or less and the ratio of the thickness of the metal plate to the diameter of the through hole is 1 or more, preferably, 1.2 or more. Hence, the wiring board is allowed to have a measure of strength and high density packaging.

### EMBODIMENT

Next, an embodiment of the method for manufacturing a wiring board, by which through holes are made in the metal plate used for the wiring board as described above, will be described. A manufacturing process includes the first step for performing initial half etching and the second step for performing etching after the first step.

As the first step, first, a 42-alloy plate of 0.3 mm in thickness as a metal plate was immersed in acetone, thereby being degreased and cleaned, and both surfaces of the immersed degreased cleaned 42-alloy plate were coated with a resist. The both surfaces were spin-coated with a photoresist (OFPR-800, made by Tokyo Ohka Kogyo Co., Ltd.). A pattern for forming the through holes was exposed by a double sided exposure and then was developed by a developing solution (NMD-3, made by Tokyo Ohka Kogyo Co., Ltd.). The developing time was about 60 seconds.

Next, the 42-alloy plate was subjected to immersion etching by an etching solution of iron (III) chloride. The 42-alloy plate was subjected to half etching so that an etching depth was about from 20 μm to 30 μm. The 42-alloy plate subjected to the half etching was cleaned to remove the photoresist therefrom. Acetone was used for the cleaning solution. Up to this point, the first step was completed.

As the second step, the 42-alloy plate subjected to the half etching was coated with the photoresist by electrodeposition resist. A photoresist film having a film thickness of 7 μm to 9 μm was formed by the electrodeposition resist coating using SONNE EDUVP 600SA made by Kansai Paint Co., Ltd. as the electrodeposition resist material at a current of 5 A/m² for about 90 seconds. The photoresist film was dried in an oven at about 100° C. for 5 to 10 minutes.

The photoresist film was aligned to the pattern used for the half etching for forming the through holes and was exposed to light. The amount of exposure was set at about 350 mJ/cm². In order to stabilize the photoresist film, the exposed 42-alloy plate was prebaked. The prebaking of the photoresist film was performed at 140° C. for about 10 minutes.

The pre-baked 42-alloy plate was developed. The developing of the 42-alloy plate was performed by immersing the 42-alloy in a water solution of Na₂CO₃ having a concentration of 0.5 to 1.0% at a solution temperature of 40° C. for about 2 minutes. After the plate was developed, the plate was rinsed with water and then etched. The plate was subjected to immersion etching using an etching solution of iron (III) chloride. After the plate was etched, the photoresist film was removed. The removing of the photoresist film was performed by immersing the plate in a caustic soda solution having a concentration of about 3% at a solution temperature of 50° C. for about 2 minutes. Up to this point, the second step was completed.

Furthermore, the second step was repeated four times, whereby the through hole having a diameter of about 60 μm could be made in the 42-alloy of 300 μm in thickness. The ratio of the thickness of the metal plate to the diameter of the through hole was 5.0.

The wiring board of the invention could be manufactured by using the 42-alloy plate, which has the through holes manufactured by the above-described manufacturing method, as the metal plate.

The method for manufacturing a wiring board in accordance with the invention can be applied to a method for manufacturing various kinds of wiring boards having a metal plate as a base plate.

1. A wiring board comprising:
a metal plate that has a through hole formed so as to pass though both surfaces thereof by isotropic etching;
an insulating layer that covers both surfaces of the metal plate and an inside surface of the through hole;
a wiring layer formed on an upper surface of at least one surface of the insulating layer; and
a conductive via electrode formed in the through hole, characterized in that a diameter of the through hole is 100 μm or less and a ratio of a thickness of the metal plate to the diameter of the through hole is 1 or more.

2. The wiring board according to claim 1, characterized in that the isotropic etching is wet etching.

3. A method for manufacturing a wiring board comprising the steps of, so as to form a through hole in a metal plate: subjecting one surface or both surfaces of a metal plate to photoresist coating at least one time, and then to exposing, developing, and isotropic etching; and subjecting both surfaces of the metal plate to photoresist coating at least one time, and then to exposing, developing, and isotropic etching.

4. The method for manufacturing a wiring board according to claim 3, characterized in that the isotropic etching is wet etching.

5. The method for manufacturing a wiring board according to claim 3 or claim 4, characterized in that the photoresist coating after at least two times is performed by an electrodeposition photoresist coating.
